(19) United States
(12) Patent Application Publication
(10) Pub. No.: US 2014/0368183 A1
(43) Pub. Date: Dec. 18, 2014

(54) SYSTEM AND METHOD FOR LINEAR MEASUREMENT OF AC WAVEFORMS WITH LOW VOLTAGE NON-LINEAR SENSORS IN HIGH VOLTAGE ENVIRONMENTS

(71) Applicant: Awesense Wireless Inc., Kelowna (CA)

(72) Inventors: Mischa Steiner-Jovic, Kelowna (CA); Rick Slamka, Kelowna (CA)

(73) Assignee: Awesense Wireless Inc., Kelowna (CA)

(21) Appl. No.: 14/373,015

(22) PCT Filed: Jan. 21, 2013
(86) PCT No.: PCT/CA2013/000059

§ 371 Date: Jul. 17, 2014

Related U.S. Application Data
(60) Provisional application No. 61/588,557, filed on Jan. 19, 2012.

(51) Int. Cl. G01R 19/00; G01R 19/25; G01R 35/00

(52) U.S. Cl. CPC G01R 19/0092; G01R 35/00; G01R 19/25
USPC 324/76.11

(57) ABSTRACT

A method of correcting the non-linearity of a sensor on a linear, high voltage power line comprises removably fixing a sensor on a conductor carrying an AC signal amplifying the current signal and calculating and calibrating a desired gain such that a non-linear signal from the sensor is converted to a linear signal.

### FIELD OF THE INVENTION

The present invention to the field of accurately measuring AC waveforms in high voltage environments.

### BACKGROUND OF THE INVENTION

Electric-power transmission is the bulk transfer of electrical energy, from generating power plants to electrical substations located near demand centers. This is distinct from the local wiring between high-voltage substations and customers, which is typically referred to as electric power distribution. Transmission lines, when interconnected with each other, become transmission networks. Transmission lines mostly use high-voltage three-phase alternating current (AC).

AC is the form in which electric power is delivered to businesses and residences. The usual waveform of an AC power circuit is a sine wave. With AC, the flow of electric charge reverses periodically, unlike direct current. It starts from zero, grows to a maximum, decreases to zero, reverses, reaches a maximum in the opposite direction, returns again to zero, and repeats the cycle indefinitely. The time taken to complete one cycle is called the period, the number of cycles per second the frequency and the maximum value in either direction, the current's amplitude. Low frequencies (50-60 cycles per second) are used for domestic and commercial power, but frequencies of around 100 million cycles per second (100 megahertz) are used in television and of several thousand megahertz in radar and microwave communication. A major advantage of AC is that the voltage can be increased and decreased by a transformer for more efficient transmission over long distances. In contrast, direct current (DC) cannot use transformers to change voltage.

With respect to AC power, an ideal transformer reduces voltage (V) and increases current (I) so that the power IV is constant. A neighborhood substation typically reduces the voltage to a reasonable value for street lines and then a small transformer outside and/or inside a residence further reduces it to 110 V (220 in Europe). Since the current and voltage are alternating with sine waves, as noted above, the power delivered to, for example, an appliance also oscillates. The current or voltage oscillation frequency is 60 cycles/sec (60 Hz) in the US and 50 Hz in Europe

Electricity is transmitted at these noted high voltages to reduce the energy lost in long-distance transmission. A key limitation in the distribution of electricity is that, with minor exceptions, electrical energy cannot be stored, and therefore must be generated as needed. A sophisticated system of measurement and control is therefore required to ensure electric generation very closely matches the demand. If supply and demand are not in balance, generation plants and transmission equipment can shut down which, in the worst cases, can lead to a major regional blackout, such as occurred in the US Northeast blackouts of 1965, 1977, 2003, and in the west, in 1996 and 2011. To reduce the risk of such failures, electric transmission networks are interconnected into regional, national or continental wide networks thereby providing multiple redundant alternate routes for power to flow should (weather or equipment) failures occur. Much analysis is done by transmission companies to determine the maximum reliable capacity of each line (ordinarily less than its physical or thermal limit) to ensure spare capacity is available should there be any such failure in another part of the network.

There is a need for a system that can be placed through the electrical grid network to determine where these loss events are occurring. Measuring and monitoring high voltage lines, in particular transmission and distribution lines, in an accurate way presents significant challenges.

Current Transformers (CT) are presently used for measuring current in AC lines when direct measurement is not possible because of high voltages, high current or physical constraints. An ideal CT would provide a signal exactly proportional to the desired measurement target. However, no perfectly ideal current transformer exists, and all CT's on the market suffer from some degree of non-linearity, especially near the minimum and maximum current they are designed to measure. For this reason, typical CT solutions available are accurate only within the linear portion of their response curve.

Typically, a CT is accurate from it's maximum rated load to a minimum that is 10% of the maximum. For example, a CT suitable for loads up to 100 A is only accurate down to 10 A. This leaves the sensor unable to accurately measure a load below 10 A. Similar situations can arise when using Rogowski Coil measurement sensors, where they are not suitable for signals below certain power levels.

A CT does provide a proportional signal for low current levels below its rated minimum, however it does not relate to the input current the same as for high current levels. Also, as the output signal is very small at this point, it is very susceptible to Electromagnetic Interference (EMI), supply voltage fluctuations and measurement inaccuracies.

Causes on non-linearity include:
permeability of the CT core
nickel-steel and the types of doping materials and the level of impurity, that is present in the material
temperature
grade of the copper wire wrapped around the CT

It would be desirable to increase the provider's knowledge of the electrical properties in their high voltage networks by closely monitoring the networks and specifically to measure AC waveforms in a linear manner. This way, electricity providers can significantly reduce the amount of electricity lost in such networks and make considerable savings in the cost of generating the electricity. Furthermore, by closely monitoring their networks, electricity providers will be in a better position to correct faults in their networks quickly with a minimum of inconvenience to their customers, thereby providing an improved quality of efficient supply.

It is an object of the present invention to obviate or mitigate the above disadvantages.

### SUMMARY OF THE INVENTION

The present invention provides, in one aspect, a method of correcting the non-linearity of a sensor on a high voltage power line which comprises:
a) removably fixing a sensor on a conductor carrying an AC signal;
b) amplifying the current signal; and
c) calculating and calibrating a desired gain such that a non-linear signal from the sensor is converted to a linear signal.

The present invention provides, in another aspect, a system for measuring AC waveforms in high voltage environments comprises:
a) a sensor device fixable on a conductor carrying AC current at high voltage;
b) means to amplify current; and
c) a microprocessor to digitize AC current signal and to calibrate, and select a desired gain such that a non-linear signal from the sensor device is converted to a linear signal

The present invention provides, in another aspect, a system for measuring AC waveforms in high voltage environments which comprises:
a) a sensor device fixable on a conductor carrying AC current at high voltage;
b) means to amplify current;
c) a microprocessor;
d) computer readable memory including computer readable instructions, which, when executed by the processor, cause the processor to perform to the following steps:
   i) digitize AC current signal; and
   ii) calibrate and select a desired gain such that a non-linear signal from the sensor device is converted to a linear signal.

The present invention provides, in another aspect, a non-transitory processor readable medium storing code representing instructions to cause a processor to of correcting the non-linearity of a sensor on a high voltage power line comprising:
a) removably fixing a sensor on a conductor carrying an AC signal;
b) amplifying the current signal; and
c) calculating and calibrating a desired gain such that a non-linear signal from the sensor is converted to a linear signal.

The present invention provides, in another aspect, a system for measuring AC waveforms in high voltage environments comprises:
a) a sensor device fixable on a conductor carrying AC current at high voltage;
b) means to amplify current; and
c) a microprocessor to digitize AC current signal and to calibrate, and select a desired gain such that a non-linear signal from the sensor device is converted to a linear signal

The present invention provides, in another aspect, protected low voltage, non-linear sensors which may be used in high voltage environments.

Various aspects of this method for using non-linear low cost sensors in the high voltage environment may have one or more of the following features:
Versatile in manufacturing
Ability to produce larger numbers of higher accurate sensors
Lower cost application for the industry
Lower cost materials needed for the sensor
Increased effective dynamic range
Multi-tap (multi-ratio) CT not required
Resilient to high voltage Electro-Magnetic Pulses (EMP)

The device, method and system of the present invention afford many advantages. As noted above, CT does not relate to the input current the same as for high current levels and, as the output signal is very small at this point, it is very susceptible to EMI, supply voltage fluctuations and measurement inaccuracies. The present invention solves these problems using a signal amplification that has several discrete gain levels, each of which may be calibrated individually.

The system and method of the present invention provides stable, linear and accurate measurements of AC waveforms in high voltage environments using low voltage non-linear sensors. These sensors are placed on electrical utility wires and need to be highly accurate as a result of industry demands. Until now, there has not been a way to use lower cost materials, and thus lower cost sensors, in these environments.

### DESCRIPTION OF THE FIGURES

The following figures set forth embodiments in which like reference numerals denote like parts. Embodiments are illustrated by way of example and not by way of limitation in all of the accompanying figures.

FIG. 1 is a flow chart diagram of a method of correcting the non-linearity of a sensor according to one aspect of the invention;

FIG. 2 is a graph illustrating the splitting of the measurable range into a plurality of discrete sub-ranges.

FIG. 3 is a graphic representation of the conversion of signal from non-linear to linear form;

FIG. 4 is perspective view of CT on a wire; and

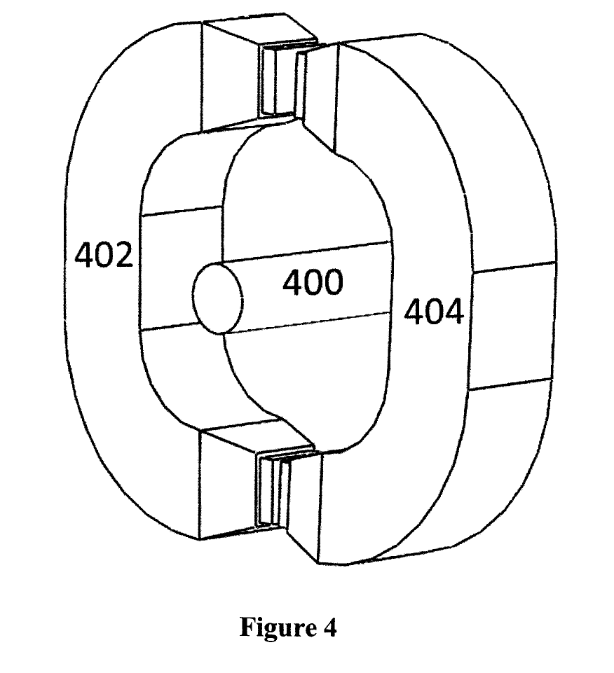

FIG. 5 is a flowchart of the basic process steps in a feedback loop, operating in a non-high voltage environment wherein the system resets checks to determine whether it is at or near high voltages.

### PREFERRED EMBODIMENTS OF THE INVENTION

A method, system and device for correcting the non-linearity of a sensor on a high voltage power line are described herein. A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Unless specifically stated otherwise, it is appreciated that throughout the description, discussions utilizing terms such as “processing” or “computing” or “calculating” or “determining” or “displaying” or the like, (for example, a microprocessor “digitizing” an AC current and “calibrating” and “selecting” a desire gain) refer to the action and processes of a data processing system, or similar electronic computing device, that manipulates and transforms data represented as physical (electronic) quantities within the computer system's registers and memories into other data similarly represented as physical quantities within the computer system memories or registers or other such information storage, transmission or display devices.

The algorithms and displays with the applications described herein are not inherently related to any particular computer or other apparatus. Various general-purpose systems may be used with programs in accordance with the teachings herein, or it may prove convenient to construct more specialized apparatus to perform the required machine-implemented method operations. The required structure for a variety of these systems will appear from the description below. In addition, embodiments of the present invention are not described with reference to any particular programming language. It will be appreciated that a variety of programming languages may be used to implement the teachings of embodiments of the invention as described herein.

An embodiment of the invention may be implemented as a method or as a machine readable non-transitory storage medium that stores executable instructions that, when executed by a data processing system, causes the system to perform a method. An apparatus, such as a data processing system, can also be an embodiment of the invention. Other features of the present invention will be apparent from the accompanying drawings and from the detailed description which follows.

### Terms:

The term “invention” and the like mean “the one or more inventions disclosed in this application”, unless expressly specified otherwise.

The terms “an aspect”, “an embodiment”, “embodiment”, “embodiments”, “the embodiment”, “the embodiments”, “one or more embodiments”, “some embodiments”, “certain embodiments”, “one embodiment”, “another embodiment” and the like mean “one or more (but not all) embodiments of the disclosed invention(s)”, unless expressly specified otherwise. A reference to “another embodiment” or “another aspect” in describing an embodiment does not imply that the referenced embodiment is mutually exclusive with another embodiment (e.g., an embodiment described before the referenced embodiment), unless expressly specified otherwise.

The term “variation” of an invention means an embodiment of the invention, unless expressly specified otherwise.

The terms “including”, “comprising” and variations thereof mean “including but not limited to”, unless expressly specified otherwise.

The terms “a”, “an” and “the” mean “one or more”, unless expressly specified otherwise.

The term “plurality” means “two or more”, unless expressly specified otherwise.

The term “herein” means “in the present application, including anything which may be incorporated by reference”, unless expressly specified otherwise.

The term “whereby” is used herein only to precede a clause or other set of words that express only the intended result, objective or consequence of something that is previously and explicitly recited. Thus, when the term “whereby” is used in a claim, the clause or other words that the term “whereby” modifies do not establish specific further limitations of the claim or otherwise restricts the meaning or scope of the claim.

The term “e.g.” and like terms mean “for example”, and thus does not limit the term or phrase it explains. For example, in a sentence “the computer sends data (e.g., instructions, a data structure) over the Internet”, the term “e.g.” explains that “instructions” are an example of “data” that the computer may send over the Internet, and also explains that “a data structure” is an example of “data” that the computer may send over the Internet. However, both “instructions” and “a data structure” are merely examples of “data”, and other things besides “instructions” and “a data structure” can be “data”.

The term “respective” and like terms mean “taken individually”. Thus if two or more things have “respective” characteristics, then each such thing has its own characteristic, and these characteristics can be different from each other but need not be. For example, the phrase “each of two machines has a respective function” means that the first such machine has a function and the second such machine has a function as well. The function of the first machine may or may not be the same as the function of the second machine.

The term “i.e.” and like terms mean “that is”, and thus limits the term or phrase it explains. For example, in the sentence “the computer sends data (i.e., instructions) over the Internet”, the term “i.e.” explains that “instructions” are the “data” that the computer sends over the Internet.

Any given numerical range shall include whole and fractions of numbers within the range. For example, the range “1 to 10” shall be interpreted to specifically include whole numbers between 1 and 10 (e.g., 1, 2, 3, 4, . . . 9) and non-whole numbers (e.g. 1.1, 1.2, . . . 1.9).

Where two or more terms or phrases are synonymous (e.g., because of an explicit statement that the terms or phrases are synonymous), instances of one such term/phrase does not mean instances of another such term/phrase must have a different meaning. For example, where a statement renders the meaning of “including” to be synonymous with “including but not limited to”, the mere usage of the phrase “including but not limited to” does not mean that the term “including” means something other than “including but not limited to”.

Within the scope of the present invention, the “power factor” of an AC electric power system is defined as the ratio of the real power flowing to the load to the apparent power in the circuit, and is a dimensionless number between 0 and 1 (frequently expressed as a percentage, e.g. 0.5 pf=50% pf). Real power is the capacity of the circuit for performing work in a particular time. Apparent power is the product of the current and voltage of the circuit. Due to energy stored in the load and returned to the source, or due to a non-linear load that distorts the wave shape of the current drawn from the source, the apparent power will be greater than the real power. In other words, the power factor is the ratio between real power and apparent power in a circuit. It is a practical measure of the efficiency of a power distribution system. For two systems transmitting the same amount of real power, the system with the lower power factor will have higher circulating currents due to energy that returns to the source from energy storage in the load. These higher currents produce higher losses and reduce overall transmission efficiency. A lower power factor circuit will have a higher apparent power and higher losses for the same amount of real power.

The power factor is one when the voltage and current are in phase. It is zero when the current leads or lags the voltage by 90 degrees. Power factors are usually stated as “leading” or “lagging” to show the sign of the phase angle, where leading indicates a negative sign.

Within the scope of the invention, AC is generally measured by transformers, such as current transformers (CT). The current to be measured is forced through the primary winding (often a single turn) and the current through the secondary winding is found by measuring the voltage across a current-sense resistor (or “burden resistor”). The secondary winding has a burden resistor to set the current scale. The core of some current transformers is split and hinged; it is opened and clipped around the wire to be sensed, then closed, making it unnecessary to free one end of the conductor and thread it through the core. Another clip-on design is the Rogowski coil. It is a magnetically balanced coil that measures current by electronically evaluating the line integral around a current.

In use, current flowing through an overhead line will generate a magnetic field surrounding that line. The CT transforms this magnetic field into a voltage.

With the scope of the present invention, “harmonics” are defined as, “integral multiples of the fundamental frequency. AC power is delivered throughout the distribution system at a fundamental frequency of 60 Hz. (50 Hz in Europe.) As such, the 3rd harmonic frequency is 180 Hz, the 5th is 300 Hz, etc. In the US, the standard distribution system in commercial facilities is 208/120 wye. There are three phase wires and a neutral wire. The voltage between any two phase wires is 208, and the voltage between any single phase wire and the neutral wire is 120. All 120 volt loads are connected between a phase and neutral. When the loads on all three phases are balanced (the same fundamental current is flowing in each phase) the fundamental currents in the neutral cancel and the neutral wire carries no current. When computer loads and other loads using switched mode power supplies are connected, however, the situation changes.

Like the fundamental current, most harmonic currents cancel out on the neutral wire. However, the 3rd harmonic current, instead of canceling, is additive in the neutral. Thus if each phase wire were carrying, in addition to fundamental current, 100 amps of 3rd harmonic current, the neutral wire could be carrying 300 amps of 3rd harmonic current. In many cases, neutral-wire current can exceed phase wire currents. This extra current provides no useful power to the loads. It simply reduces the capacity of the system to power more loads, and produces waste heat in all the wiring and switchgear. When the 3rd harmonic current returns to the transformer it is reflected into the transformer primary where it circulates in the delta winding until it is dissipated as heat. The result is overheated neutral wires, switchgear, and transformers. This can lead to failure of some part of the distribution system and, in the worst case, fires. In addition, waste heat in all parts of the system increases energy losses and results in higher electrical bills. It is estimated that 3rd harmonic currents can increase electrical costs by as much as 8%.

Switch mode power supplies draw current in spikes, which requires the AC supply to provide harmonic currents. The largest harmonic current generated by the SMPS is the 3rd. The magnitude of this harmonic current can be as large as or larger than the fundamental current. Also generated, in smaller amounts, are the 5th, 7th, and all other odd harmonic currents.

With the scope of the present invention, “transients” are defined, (whether currents or voltages), as occurrences which are created fleetingly in response to a stimulus or change in the equilibrium of a circuit. Transients frequently occur when power is applied to or removed from a circuit, because of expanding or collapsing magnetic fields in inductors or the charging or discharging of capacitors.

With the scope of the present invention, “phase angle or phase or current (φ”, is the angle of difference (in degrees) between voltage and current; Current lagging Voltage (Quadrant I Vector), Current leading voltage (Quadrant IV Vector).

The present disclosure relates to a method of measuring linear high voltage AC waveforms using a low voltage, non-linear sensor. The present invention further provides a method of correcting the non-linearity of a low voltage, non-linear sensor to enable measurement of voltage AC waveforms.

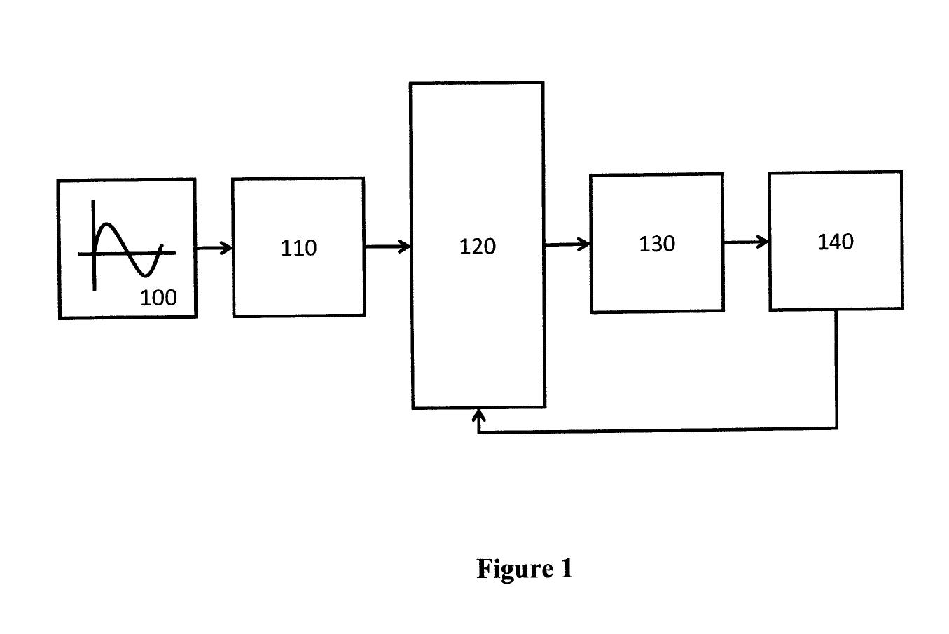

FIG. 1 describes the method of correcting for the non-linearity of the sensor of the invention. The current transformer [110] is fixed on the conductor that carries the AC current [100] we wish to measure. This induces an AC current on the current transformer output that is proportional to the current passing through the target conductor. This signal is amplified by the Gain Stage [120], then sent to a circuit [130] which converts the AC signal to an equivalent DC voltage which is representative of the Root Mean Square (RMS) equivalent. The Central Processing Unit (CPU) [140], consisting of a micro-controller, microprocessor or other processing circuit, reads the DC voltage using an analog-to-digital converter. Software within the CPU uses the calibration parameters specific to the currently selected gain factor to convert the digitized DC voltage into a final value representative of the current passing through the target conductor. Alternatively, the CPU can be fed a digitized representation of the AC signal that it can process in the digital domain.

The software within the CPU has control of the Gain Stage unit and is able to select the desired gain. When software detects that the signal has gone above a certain point, it signals the Gain Stage to select a smaller gain so that the DC signal remains within the specified range of the ADC unit. When the signal goes below the point where the current gain stage is appropriate, it signals the Gain Stage unit to switch to a higher gain.

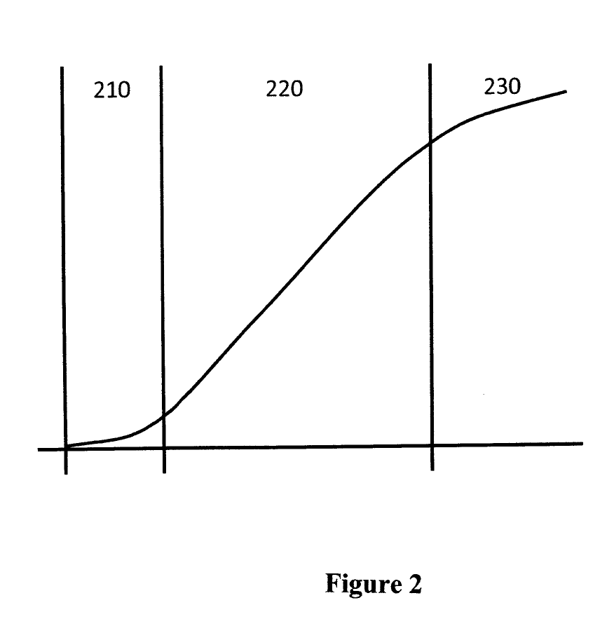

FIG. 2 illustrates the splitting of the measurable range into a plurality of discrete sub-ranges. There is no set number of ranges. This method is applicable for ranges 1 to n, where ‘n’ is a number determined by the application and non-linearity of the sensor. This method describes how to calibrate each of these sub-ranges independently. This solves the problem of non-linearity within the complete range of the sensor.

A sensor may have multiple stages of non-linearity throughout its capable signal range. For instance, a Current Transformer (CT) sensor capable of measuring amperages from 0-100 A may have non-linear measurement characteristics below 1 A [210] and above 95 A [230]. Without compensation, this would lead to inaccuracy in measurements in these ranges and would leave only the 1 A-95 A [220] range with usable accuracy. Furthermore, there may be other non-linear areas throughout the measurement range of the sensor that need to be characterized and compensated for.

By splitting the range into sub-ranges, there is provided herein an ability to use a distinct calibration for each sub-range. While a single linear calibration over the entire range would result in inaccuracies outside of acceptable limits, each sub-range with its own distinct calibration is able to meet the required accuracy. In this way, the entire range may be measured accurately.

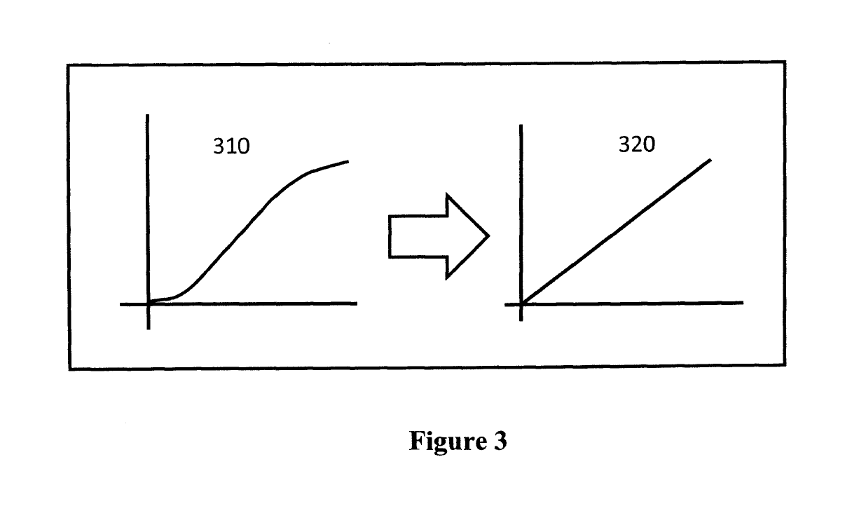

FIG. 3 illustrates the result of the process. On the left [310] is the initial non-linear output of the current transformer. On the right [320] is the resulting signal after being processed according to the system and method described herein.

Within the high-voltage environment, issues arise when devices and sensors enter and exit the high-voltage field. This voltage can be typically thought of anything higher than 600V on a conducting wire that can be insulated or non-insulated. A high strength Electric Field (E-Field) and Magnetic (B-Field) exist in this environment. When devices enter and exit this environment voltages and currents are induced on metallic surfaces resulting in eddy currents and non-metallic surfaces resulting in static charges. Other conditions that can occur include:
Induced electric arcing between the high-voltage electric wire and the device or sensor
Induced voltages and charges on the device or sensor
Induced currents and eddy's on the device or sensor
Electromagnetic Pulses (EMP) being present on the device or sensor as a result of the oscillating voltage and current in an AC electric voltage environment

These issues compound when using low voltage sensors in a high-voltage environment. As the nature of low voltage sensors are, they are not designed to be resilient to the aforementioned effects that are present in a high-voltage environment.

In order to use low-voltage sensors in high-voltage environments, protection must be implemented. This protection may include all or any of the following:
Using high dielectric compound coating on the sensor to help prevent or reduce arcing from the high-voltage wire to edges and faces of the sensor
Using protection circuitry to not allow EMP pulses to transfer and propagate through circuitry
Using specifically designed software methods to detect and determine when high-voltage conditions are occurring, and take the necessary steps to prevent failure and create a recovery schedule.

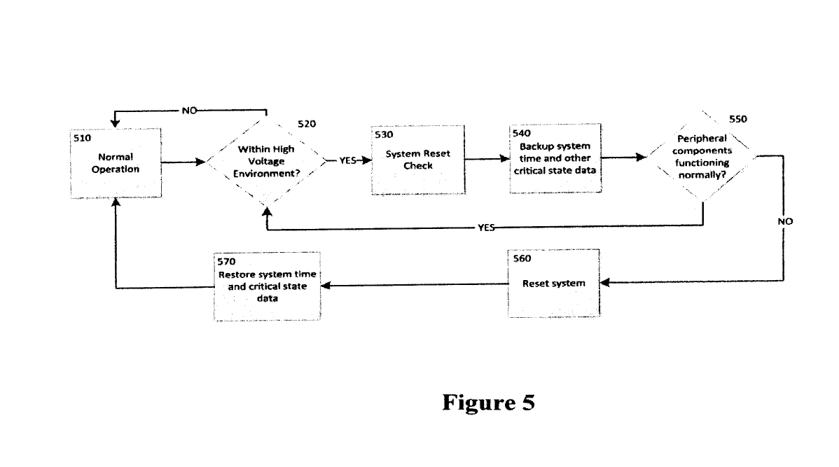

FIG. 5 is a flowchart illustrating the basic operation of the “processing” portion of the system. [510] represents the normal operation of the device when not in a high-voltage environment. The system must [520] continually monitor the environment to determine whether it is near high voltages. The system uses a form of system reset check [530] to ensure that should an EMP pulse disrupt system operation, the complete system will automatically reset. While running within a high voltage environment, continual backups are made of critical system state data such as the current system time [540]. Components peripheral to the CPU are continually monitored to ensure correct operation [550]. Should an EMP cause a peripheral to malfunction, a system reset is initiated [560]. Upon system restart, the critical state data that was backed up [540] is read, verified valid and restored [570].

Furthermore, the sensor data can be measured, collected, and stored. This data can be then transmitted through a network or other method that transfers measurement data from one point to another. This sensor data can be used as a measurement in the electrical system which is useful for determining operations of the system.

Those skilled in the relevant art will appreciate that the sensors described herein may be implemented and/or calibrated with a computing system, including networks. In this regard, the following information is instructive of such computing environments.

Such aspects of the invention may be practiced with any computer configurations, including hand-held devices, multiprocessor systems, microprocessor-based or programmable consumer electronics, personal computers (“PCs”), network PCs, mini-computers, mainframe computers, and the like. In one aspect, the measurement data is communicated wirelessly on a peer-to-peer network to a central network manager. In one aspect, the system comprises a plurality of sensors.

Within the scope of the present invention, data acquisition may preferably be controlled by a computer or microprocessor. As such, the invention can be implemented in numerous ways, including as a process, an apparatus, a system, a computer readable medium such as a computer readable storage medium or a computer network wherein program instructions are sent over optical or communication links. In this specification, these implementations, or any other form that the invention may take, may be referred to as systems or techniques. A component such as a processor or a memory described as being configured to perform a task includes both a general component that is temporarily configured to perform the task at a given time or a specific component that is manufactured to perform the task. In general, the order of the steps of disclosed processes may be altered within the scope of the invention.

The following discussion provides a brief and general description of a suitable computing environment in which various embodiments of the system may be implemented. In particular, this is germane to the network managers, which aggregate measurement data and downstream to the servers which enables viewing of the data by a user at an interface.

Although not required, embodiments will be described in the general context of computer-executable instructions, such as program applications, modules, objects or macros being executed by a computer. Those skilled in the relevant art will appreciate that the invention can be practiced with other computer configurations, including hand-held devices, multiprocessor systems, microprocessor-based or programmable consumer electronics, personal computers (“PCs”), network PCs, mini-computers, mainframe computers, and the like. The embodiments can be practiced in distributed computing environments where tasks or modules are performed by remote processing devices, which are linked through a communications network. In a distributed computing environment, program modules may be located in both local and remote memory storage devices.

A computer system may be used as a server including one or more processing units, system memories, and system buses that couple various system components including system memory to a processing unit. Computers will at times be referred to in the singular herein, but this is not intended to limit the application to a single computing system since in typical embodiments, there will be more than one computing system or other device involved. Other computer systems may be employed, such as conventional and personal computers, where the size or scale of the system allows. The processing unit may be any logic processing unit, such as one or more central processing units (“CPUs”), digital signal processors (“DSPs”), application-specific integrated circuits (“ASICs”), etc. Unless described otherwise, the construction and operation of the various components are of conventional design. As a result, such components need not be described in further detail herein, as they will be understood by those skilled in the relevant art.

A computer system includes a bus, and can employ any known bus structures or architectures, including a memory bus with memory controller, a peripheral bus, and a local bus. The computer system memory may include read-only memory (“ROM”) and random access memory (“RAM”). A basic input/output system (“BIOS”), which can form part of the ROM, contains basic routines that help transfer information between elements within the computing system, such as during startup.

The computer system also includes non-volatile memory. The non-volatile memory may take a variety of forms, for example a hard disk drive for reading from and writing to a hard disk, and an optical disk drive and a magnetic disk drive for reading from and writing to removable optical disks and magnetic disks, respectively. The optical disk can be a CD-ROM, while the magnetic disk can be a magnetic floppy disk or diskette. The hard disk drive, optical disk drive and magnetic disk drive communicate with the processing unit via the system bus. The hard disk drive, optical disk drive and magnetic disk drive may include appropriate interfaces or controllers coupled between such drives and the system bus, as is known by those skilled in the relevant art. The drives, and their associated computer-readable media, provide non-volatile storage of computer readable instructions, data structures, program modules and other data for the computing system. Although a computing system may employ hard disks, optical disks and/or magnetic disks, those skilled in the relevant art will appreciate that other types of non-volatile computer-readable media that can store data accessible by a computer system may be employed, such a magnetic cassettes, flash memory cards, digital video disks (“DVD”), Bernoulli cartridges, RAMs, ROMs, smart cards, etc.

Various program modules or application programs and/or data can be stored in the computer memory. For example, the system memory may store an operating system, end user application interfaces, server applications, and one or more application program interfaces (“APIs”).

The computer system memory also includes one or more networking applications, for example a Web server application and/or Web client or browser application for permitting the computer to exchange data with sources via the Internet, corporate Intranets, or other networks as described below, as well as with other server applications on server computers such as those further discussed below. The networking application in the preferred embodiment is markup language based, such as hypertext markup language (“HTML”), extensible markup language (“XML”) or wireless markup language (“WML”), and operates with markup languages that use syntactically delimited characters added to the data of a document to represent the structure of the document. A number of Web server applications and Web client or browser applications are commercially available, such those available from Mozilla and Microsoft.

The operating system and various applications/modules and/or data can be stored on the hard disk of the hard disk drive, the optical disk of the optical disk drive and/or the magnetic disk of the magnetic disk drive.

A computer system can operate in a networked environment using logical connections to one or more client computers and/or one or more database systems, such as one or more remote computers or networks. A computer may be logically connected to one or more client computers and/or database systems under any known method of permitting computers to communicate, for example through a network such as a local area network (“LAN”) and/or a wide area network (“WAN”) including, for example, the Internet. Such networking environments are well known including wired and wireless enterprise-wide computer networks, intranets, extranets, and the Internet. Other embodiments include other types of communication networks such as telecommunications networks, cellular networks, paging networks, and other mobile networks. The information sent or received via the communications channel may, or may not be encrypted. When used in a LAN networking environment, a computer is connected to the LAN through an adapter or network interface card (communicatively linked to the system bus). When used in a WAN networking environment, a computer may include an interface and modem or other device, such as a network interface card, for establishing communications over the WAN/Internet.

In a networked environment, program modules, application programs, or data, or portions thereof, can be stored in a computer for provision to the networked computers. In one embodiment, the computer is communicatively linked through a network with TCP/IP middle layer network protocols; however, other similar network protocol layers are used in other embodiments, such as user datagram protocol (“UDP”). Those skilled in the relevant art will readily recognize that these network connections are only some examples of establishing communications links between computers, and other links may be used, including wireless links.

While in most instances a computer will operate automatically, where an end user application interface is provided, a user can enter commands and information into the computer through a user application interface including input devices, such as a keyboard, and a pointing device, such as a mouse. Other input devices can include a microphone, joystick, scanner, etc. These and other input devices are connected to the processing unit through the user application interface, such as a serial port interface that couples to the system bus, although other interfaces, such as a parallel port, a game port, or a wireless interface, or a universal serial bus (“USB”) can be used. A monitor or other display device is coupled to the bus via a video interface, such as a video adapter (not shown). The computer can include other output devices, such as speakers, printers, etc.

It is to be fully understood that the present methods, systems and devices also may be implemented as a computer program product that comprises a computer program mechanism embedded in a computer readable storage medium. For instance, the computer program product could contain program modules. These program modules may be stored on CD-ROM, DVD, magnetic disk storage product, flash media or any other computer readable data or program storage product. The software modules in the computer program product may also be distributed electronically, via the Internet or otherwise, by transmission of a data signal (in which the software modules are embedded) such as embodied in a carrier wave.

For instance, the foregoing detailed description has set forth various embodiments of the devices and/or processes via the use of examples. Insofar as such examples contain one or more functions and/or operations, it will be understood by those skilled in the art that each function and/or operation within such examples can be implemented, individually and/or collectively, by a wide range of hardware, software, firmware, or virtually any combination thereof. In one embodiment, the present subject matter may be implemented via ASICs. However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof, and that designing the circuitry and/or writing the code for the software and or firmware would be well within the skill of one of ordinary skill in the art in light of this disclosure.

In addition, those skilled in the art will appreciate that the mechanisms taught herein are capable of being distributed as a program product in a variety of forms, and that an illustrative embodiment applies equally regardless of the particular type of signal bearing media used to actually carry out the distribution. Examples of signal bearing media include, but are not limited to, the following: recordable type media such as floppy disks, hard disk drives, CD ROMs, digital tape, flash drives and computer memory; and transmission type media such as digital and analog communication links using TDM or IP based communication links (e.g., packet links).

While the forms of sensor/CT/device, method and system described herein constitute preferred embodiments of this invention, it is to be understood that the invention is not limited to these precise forms. As will be apparent to those skilled in the art, the various embodiments described above can be combined to provide further embodiments. Aspects of the present systems, methods and sensors (including specific components thereof) can be modified, if necessary, to best employ the systems, methods, nodes and components and concepts of the invention. These aspects are considered fully within the scope of the invention as claimed. For example, the various methods described above may omit some acts, include other acts, and/or execute acts in a different order than set out in the illustrated embodiments.

Further, in the methods taught herein, the various acts may be performed in a different order than that illustrated and described. Additionally, the methods can omit some acts, and/or employ additional acts.

These and other changes can be made to the present systems, methods and articles in light of the above description. In general, in the following claims, the terms used should not be construed to limit the invention to the specific embodiments disclosed in the specification and the claims, but should be construed to include all possible embodiments along with the full scope of equivalents to which such claims are entitled. Accordingly, the invention is not limited by the disclosure, but instead its scope is to be determined entirely by the following claims.

1. A method of correcting the non-linearity of a sensor on a linear, high voltage power line which comprises:
a) removably fixing a sensor on a conductor carrying an AC signal;
b) amplifying the current signal; and
c) calculating and calibrating a desired gain such that a non-linear signal from the sensor is converted to a linear signal.

2. The method of claim 1 wherein there is provided, after step b), at least one additional step b′ is provided wherein the AC signal is converted to DC voltage, which is representative of a root mean square equivalent.

3. The method claim 1 wherein amplifying the signal provides a plurality of discrete gain levels, each capable of independent calibration.

4. The method of claim 1 wherein the sensor comprises a current transformer (CT).

5. A system for measuring AC waveforms in high voltage environments comprises:
a) a sensor device fixable on a conductor carrying AC current at high voltage;
b) means to amplify current; and
c) a microprocessor to digitize AC current signal and to calibrate and select a desired gain such that a non-linear signal from the sensor device is converted to a linear signal.

6. The system of claim 5 wherein the means to amplify current provides a plurality of discrete gain levels, each capable of independent calibration.

7. The system of claim 5 wherein the sensor comprises a current transformer (CT).

8. The system of claim 5 wherein there is additionally provided a means to convert the AC signal to DC voltage.

9. The system of claim 7 wherein the CT device comprises a Rogowski coil.

10. The system of claim 7 wherein the CT device comprises a Hall effect device.

11. The system of claim 5 wherein the conductor is a high voltage power line.

12. The system of claim 5 which comprises an analog to digital conversion means.

13. The system of claim 5 which comprises a transceiver.

14. A system for measuring AC waveforms in high voltage environments comprises:
a) a sensor device fixable on a conductor carrying AC current at high voltage;
b) means to amplify current;
c) a microprocessor;
d) computer readable memory including computer readable instructions, which, when executed by the processor, cause the processor to perform to the following steps:
i) digitize AC current signal; and
ii) calibrate and select a desired gain such that a non-linear signal from the sensor device is converted to a linear signal

15. A non-transitory processor readable medium storing code representing instructions to cause a processor to correct the non-linearity of a sensor on a high voltage power line comprising:
a) removably fixing a sensor on a conductor carrying an AC signal;
b) amplifying the current signal; and
c) calculating and calibrating a desired gain such that a non-linear signal from the sensor is converted to a linear signal.
